(19) United States
(12) Patent Application Publication
(10) Pub. No.: US 2022/0007108 A1
(43) Pub. Date: Jan. 6, 2022

(54) METHOD FOR IMPROVING SOUND QUALITY OF SUPER-DIRECTIONAL ULTRASONIC SPEAKER DEVICE, AND ULTRASONIC SPEAKER DEVICE HAVING SAME

(71) Applicant: CATCHFLOW CO., LTD., Gyeonggi-do (KR)

(72) Inventors: Tae Young KIM, Gyeonggi-do (KR); Joung Kook SEO, Gyeonggi-do (KR); Sang Hoon CHOI, Gyeonggi-do (KR)

(73) Assignee: CATCHFLOW CO., LTD., Gyeonggi-do (KR)

(21) Appl. No.: 17/289,745

(22) PCT Filed: Oct. 10, 2019
(86) PCT No.: PCT/KR2019/013258

§ 371 Date: Apr. 29, 2021

(30) Foreign Application Priority Data
Oct. 29, 2018 (KR) 10-2018-0130305

(51) Int. Cl. H04R 3/04; H03G 5/16

(52) U.S. Cl. CPC H04R 3/04; H04R 2217/03; H03G 5/165

(57) ABSTRACT

A method of improving sound quality of an ultrasonic speaker device includes: a first operation of removing a low frequency component of an input audio signal by using a high pass filter; a second operation of correcting a response characteristic of a signal obtained by removing the low frequency component, for each frequency band by using an equalizer; a third operation of adjusting a sound pressure level of a signal obtained by correcting the response characteristic for each frequency band; and a fourth operation of controlling a signal magnitude not to increase above a particular level by using a limiter, in order to prevent a signal clipping that may occur in the second operation and the third operation. An audio signal of improved sound quality may be transmitted to a listener by applying a sound quality improving method suitable for the characteristics of a super-directional ultrasonic speaker.

### TECHNICAL FIELD

The present disclosure relates to an ultrasonic speaker device giving super-directionality to a sound wave propagation direction through ultrasonic modulation, and more particularly, to a method of improving the sound quality of a super-directional ultrasonic speaker device and a super-directional ultrasonic speaker device including the same.

### BACKGROUND ART

A general speaker transmits sound waves in all directions in the air. However, there may be a case where sound waves are to be transmitted only in a particular direction. In this case, there is a method using a parabolic dish, in which a general speaker is installed at a focal point of the dish such that a sound output may be reflected by the dish to have straightness. However, this method has a disadvantage in that it requires a dish with a very large diameter, has a short sound reach distance, and provides poor sound quality due to mutual interference of reflected signals. In order to compensate this disadvantage, super-directional ultrasonic speaker technology has recently been implemented by using the linearity of ultrasonic waves and the nonlinear medium characteristics of the air medium. As research on sonar as underwater radar technology has advanced, super-directional ultrasonic speakers have started to be actively researched as it has been found that sounds may be transmitted even in the air like beams by using ultrasonic waves. After this, many scientists have researched the physical principle of super-directional ultrasonic speakers and how to transmit voices on ultrasonic speakers. However, super-directional ultrasonic speakers have not yet been easily commercialized, and super-directional ultrasonic speakers based on ultrasonic modulation technology have started to be commercialized only after the 2000s.

A super-directional ultrasonic speaker system uses a nonlinear interference phenomenon between an ultrasonic wave and air in the air. Theoretically, an audible signal demodulated in the air is proportional to the second-order time derivative of the square of the envelope of an amplitude-modulated signal. Accordingly, referring to FIG. 7, in a conventional ultrasonic speaker system, the square root of an input audio signal, which has been double-integrated before amplitude modulation, is amplitude-modulated and output into the air through an ultrasonic speaker. This method has a limitation in reducing a distortion because the frequency spectrum of an original audio signal with a bandwidth limited by a nonlinear operation of a square root appears on an almost infinite bandwidth. Moreover, the ATC Corporation in the USA has proposed a repetitive error compensation method without an increase in bandwidth in U.S. Pat. No. 6,584,205.

However, these literatures of the related art only paid attention to solving the nonlinear interference phenomenon between an ultrasonic wave and air and fail to propose a signal processing method for providing clearer sound quality from the viewpoint of a listener. Particularly, when a sound quality improving method suitable for the characteristics of a super-directional ultrasonic speaker is not applied, there is a problem in that an audio signal is transmitted to a listener with unnatural sound quality due to the nonlinear interference phenomenon between an ultrasonic wave and air.

(Patent Literature 001) Korean Patent Application Publication No. 10-2014-0087926 (2014.07.09.)

(Patent Literature 002) Korean Patent Publication No. 10-0622078 (2006.09.01.)

### DESCRIPTION OF EMBODIMENTS

### Technical Problem

The present disclosure is to propose a signal processing method for providing clearer sound quality to a listener in view of the above problems, and particularly, is to provide a method of improving the sound quality of a super-directional ultrasonic speaker device for transmitting an audio signal of improved sound quality to a listener by applying a sound quality improving method suitable for the characteristics of a super-directional ultrasonic speaker, and an ultrasonic speaker device including the same.

### Solution to Problem

In order to solve the above problems, according to an aspect of the present disclosure, a method of improving sound quality of an ultrasonic speaker device includes: a first operation of removing a low frequency component of an input audio signal by using a high pass filter; a second operation of correcting a response characteristic of a signal obtained by removing the low frequency component, for each frequency band by using an equalizer; a third operation of adjusting a sound pressure level of a signal obtained by correcting the response characteristic for each frequency band; and a fourth operation of controlling a signal magnitude not to increase above a particular level by using a limiter, in order to prevent a signal clipping that may occur in the second operation and the third operation. The low frequency component may be about 150 Hz or less in the first operation. The third operation of adjusting the sound pressure level may remove a signal level of a first level (dB) or less not to be reproduced, compress a signal level of a second level (dB) or more, and give other signal levels a gain of 4 dB or more.

Also, according to another aspect of the present disclosure, an ultrasonic speaker device includes a sound quality improver including: a high pass filter configured to remove a low frequency component of an input audio signal; an equalizer configured to correct a response characteristic of a signal obtained by removing the low frequency component through the high pass filter, for each frequency band; a sound pressure level corrector configured to adjust a sound pressure level of a signal obtained by correcting the response characteristic for each frequency band; and a limiter configured to control a signal magnitude not to increase above a particular level, in order to prevent a signal clipping that may occur in the equalizer and the sound pressure level corrector. The low frequency component may be about 150 Hz or less. The sound pressure level corrector may be configured to remove a signal level of a first level (dB) or less not to be reproduced, compress a signal level of a second level (dB) or more, and give other signal levels a gain of 4 dB or more.

### Advantageous Effects of Disclosure

According to a super-directional ultrasonic speaker device of the present disclosure, an audio signal of improved sound quality may be transmitted to a listener by applying a sound quality improving method suitable for the characteristics of a super-directional ultrasonic speaker.

### BRIEF DESCRIPTION OF DRAWINGS

FIG. 1 is a diagram illustrating an overall configuration of a super-directional ultrasonic speaker device to which a sound quality improving method according to an embodiment of the disclosure is applied.

FIG. 2 is a diagram for describing a sound quality improving method according to an embodiment of the disclosure.

FIG. 3 is a diagram for describing a high pass filter according to an embodiment of the disclosure.

FIG. 4 is a diagram for describing the characteristics of an equalizer according to an embodiment of the disclosure.

FIG. 5 is a diagram for describing the characteristics of a sound pressure level corrector according to an embodiment of the disclosure.

FIG. 6 is a diagram for describing the characteristics of a limiter according to an embodiment of the disclosure.

FIG. 7 is a diagram illustrating a conventional super-directional ultrasonic system.

FIG. 8 is a diagram for describing the effects of an equalizer according to an embodiment of the disclosure.

### MODE OF DISCLOSURE

Particular structural or functional descriptions of embodiments according to the concept of the disclosure described herein are merely examples given for the purpose of describing the embodiments according to the concept of the disclosure, and the embodiments according to the concept of the disclosure may be implemented in various forms and are not limited to the embodiments described herein.

Because the embodiments according to the concept of the disclosure may have various modifications and may have various forms, the embodiments will be illustrated in the drawings and described herein in detail. However, this is not intended to limit the embodiments according to the concept of the disclosure to particular forms, and the disclosure may include modifications, equivalents, or substitutes included in the spirit and scope of the disclosure.

Although terms such as “first” and “second” may be used herein to describe various elements, these elements should not be limited by these terms. The terms are merely for the purpose of distinguishing one element from another element; for example, without departing from the scope of the disclosure according to the concept of the disclosure, a first element may also be referred to as a second element and similarly a second element may also be referred to as a first element.

When an element is referred to as being “coupled” or “connected” to another element, it should be understood that the element may be directly coupled or connected to the other element or one or more other elements may be arranged therebetween. On the other hand, when an element is referred to as being “directly coupled” or “directly connected” to another element, it should be understood that there is no other element therebetween. Expressions describing the relationship between elements, for example, “between” and “directly between” or “adjacent to” and “directly adjacent to” should be interpreted in the same manner.

The terms used herein are merely for the purpose of describing particular embodiments and are not intended to limit the scope of the disclosure. As used herein, the singular forms “a”, “an”, and “the” are intended to include the plural forms as well, unless the context clearly indicates otherwise. It will be understood that terms such as “include” and “have” used herein specify the presence of stated features, integers, steps, operations, elements, components, or combinations thereof, but do not preclude the presence or addition of one or more other features, integers, steps, operations, elements, components, or combinations thereof.

Unless otherwise defined, all terms (including technical and scientific terms) used herein may have the same meaning as commonly understood by those of ordinary skill in the art to which the disclosure belongs. It will also be understood that terms such as those defined in commonly-used dictionaries should be interpreted as having a meaning that is consistent with their meaning in the context of the relevant art and will not be interpreted in an idealized or overly formal sense unless expressly so defined herein.

Hereinafter, a method of improving the sound quality of a super-directional ultrasonic speaker device according to embodiments of the disclosure and a super-directional ultrasonic speaker device including the same will be described with reference to the accompanying drawings.

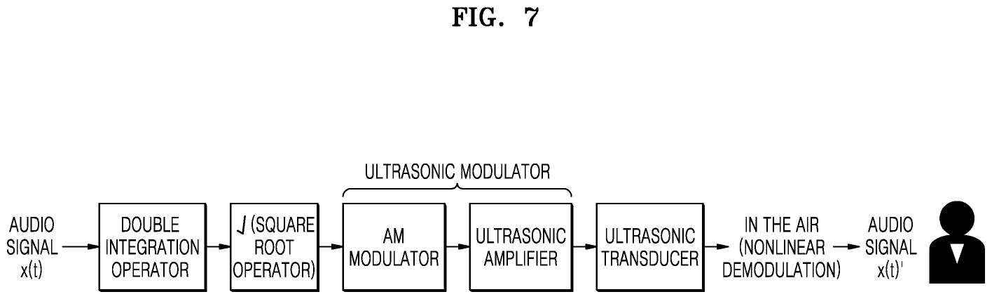

As illustrated in FIG. 7, in a conventional ultrasonic speaker system, the square root of an input audio signal, which has been double-integrated before amplitude modulation, is amplitude-modulated and output into the air through an ultrasonic speaker. This method has a limitation in reducing a distortion because the frequency spectrum of an original audio signal with a bandwidth limited by a nonlinear operation of a square root appears on an almost infinite bandwidth. Moreover, the ATC Corporation in the USA has proposed a repetitive error compensation method without an increase in bandwidth in U.S. Pat. No. 6,584,205; however, a similar distortion appears even in this case.

However, as a result of the experiment, it has been found that the size of a harmonic component caused by a nonlinear distortion is about 20 dB smaller than that of an original signal and thus it is hardly heard in general voice and audio signals. Also, it has been found that applying a sound quality improving method for improving the clarity while maximally correcting the linear distortion instead of correcting the nonlinear distortion is much more advantageous from the viewpoint of the listener because the linear distortion of the entire system should be completely measured in order to correct the nonlinear distortion and the distortion rather increases when the measurement is not accurate.

Thus, the sound quality improving method according to the disclosure is to reduce the distortion and to transmit a clearer audio signal from the viewpoint of the listener.

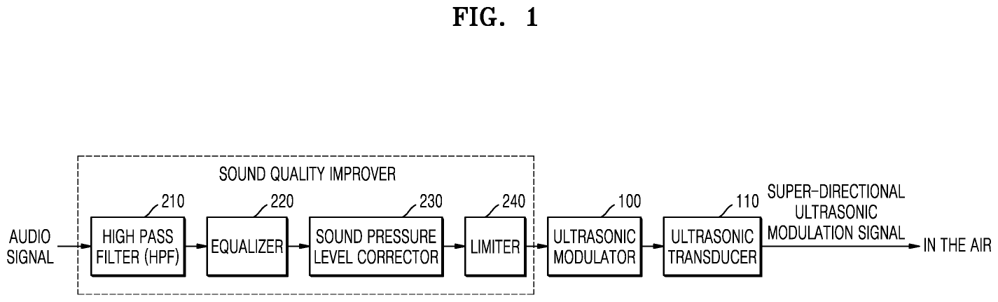

Referring to FIG. 1, in order to improve the sound quality of a super-directional ultrasonic speaker device, an ultrasonic speaker device according to the disclosure may include a sound quality improver. The sound quality improver may include: a high pass filter configured to remove a low frequency component of an input audio signal; an equalizer configured to correct a response characteristic of a signal obtained by removing the low frequency component through the high pass filter, for each frequency band; a sound pressure level corrector configured to adjust a sound pressure level of a signal obtained by correcting the response characteristic for each frequency band; and a limiter configured to control a signal magnitude not to increase above a particular level, in order to prevent a signal clipping that may occur in the equalizer and the sound pressure level corrector.

The high pass filter may be for removing a low frequency component included in the input audio signal. It is difficult for an ultrasonic speaker to reproduce a low frequency component due to the physical limitation of an ultrasonic transducer. Thus, firstly, it is necessary to remove a low frequency band, which is difficult to reproduce in the ultrasonic speaker, through a high pass filter (HPF) in order to secure the head-room required for signal amplification and to secure the loudness even with low power.

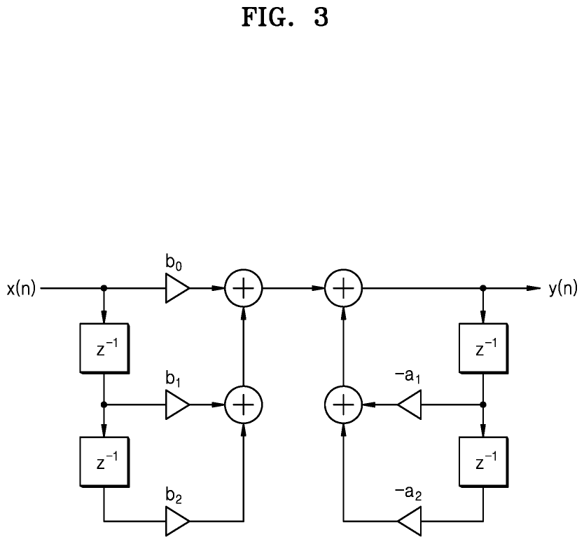

As illustrated in FIG. 3, the high pass filter used in the disclosure may be implemented as a second-order infinite impulse response (IIR) filter, and a cutoff frequency thereof may be set based on the output performance of an ultrasonic transducer used therein. The output performance of the ultrasonic transducer may be detected by identifying an audible frequency signal obtained by reproducing a single-tone signal. In the disclosure, the ultrasonic transducer is identified as being capable of effective reproduction from about 150 Hz, and based on this, a cutoff low frequency component may be about 150 Hz or less. Moreover, for ease of implementation, the high pass filter includes a second-order IIR filter structure; however, the disclosure is not limited thereto and it will be apparent that those of ordinary skill in the art may use any high pass filters having various structures when necessary.

The signal obtained by removing the low frequency component through the high pass filter may be input to the equalizer for correcting the frequency characteristics for each frequency band. The equalizer may be used to enhance the clarity while correcting the frequency response characteristics of an ultrasonic transducer, an ultrasonic amplifier (AMP), and an air column.

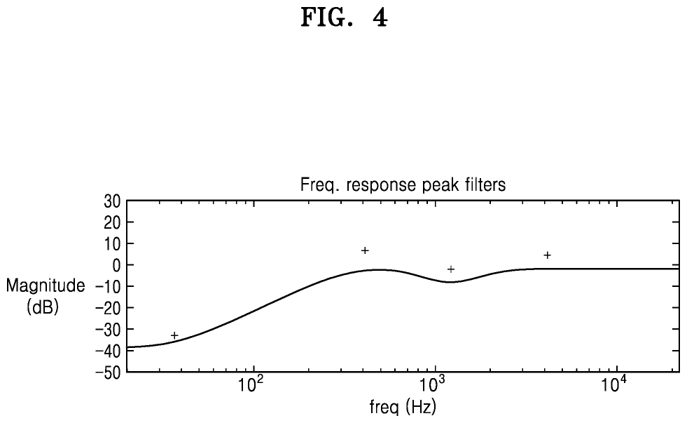

FIG. 4 illustrates a characteristic curve of an IIR equalizer set as a default value. The equalizer may be designed not only to smooth the frequency response of the air column, the ultrasonic transducer, and the ultrasonic amplifier (AMP) but also to amplify a 4 kHz band or more that is important for voice clarity. It may be apparent to those of ordinary skill in the art that the equalizer characteristic curve may be suitably adjusted as necessary in order to increase the clarity.

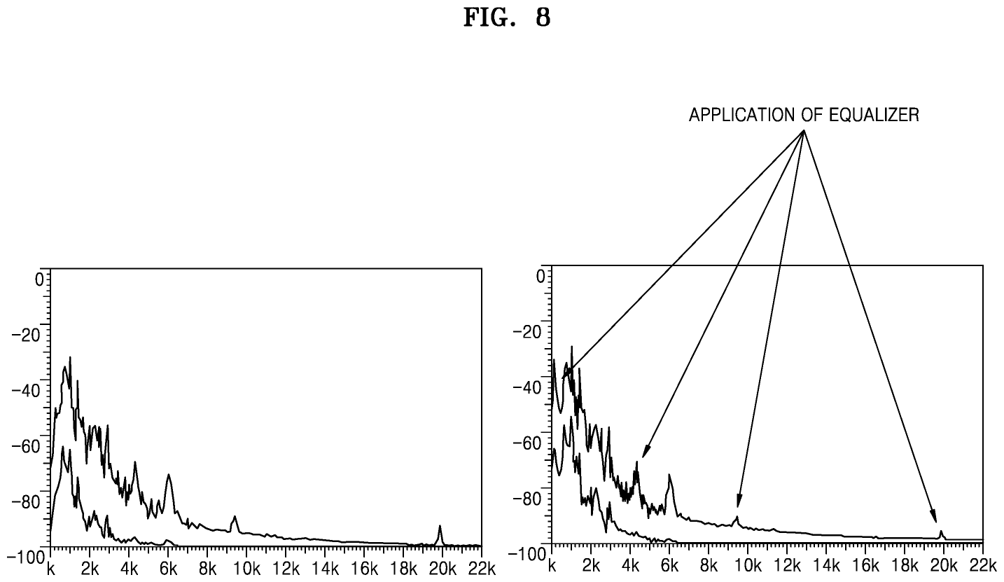

FIG. 8 is a diagram illustrating a frequency response characteristic when the equalizer is applied. The left diagram of FIG. 8 illustrates a frequency component of an original sound signal, and the right diagram illustrates a frequency component of a signal obtained when the original sound signal has passed through the equalizer. There may be an effect of reducing or removing a harmonic distortion and compensating for a bass part through the equalizer.

The signal obtained by adjusting the frequency response characteristic in the equalizer may be input to the sound pressure level corrector that adjusts the sound pressure level. For the purpose of using the ultrasonic speaker, it may be necessary to maintain the level of the reproduced sound at a desired target level, as well as high directivity to make the sound heard only to a particular user. The sound pressure level corrector may be a necessary component for this purpose, and may compress a signal of a too high level (second level), may give a signal of a certain section level a make-up gain for clarity improvement, and may remove a signal of a too low level (first level) not to be reproduced.

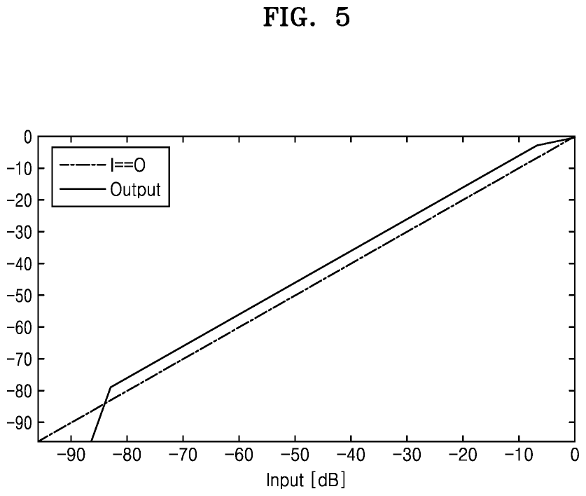

FIG. 5 illustrates a characteristic graph of the input/output level of the sound pressure level corrector. Referring to FIG. 5, in an embodiment of the disclosure, the input/output characteristics of the sound pressure level corrector may be designed such that the first level may be set to about −83 dB or less not to reproduce an input of a too low level, the second level may be set to about −7 dB or more to compress an input of a too high level, and other signal levels may be set to about 4 dB as a make-up gain.

Thus, the sound pressure level corrector may be configured to remove a signal level of a first level (dB) or less not to be reproduced, compress a signal level of a second level (dB) or more, and give other signal levels a gain of 4 dB or more.

The output of the sound pressure level corrector may be input to the limiter. The limiter may be configured to control a signal magnitude not to increase above a particular level, in order to prevent a signal clipping that may occur in the equalizer and the sound pressure level corrector. This may be because the signal clipping in the time domain that may occur in the equalizer or the sound pressure level corrector may distort the sound by generating harmonics in the frequency domain. Thus, the limiter may be used to ensure that the signal level may not increase above a certain threshold.

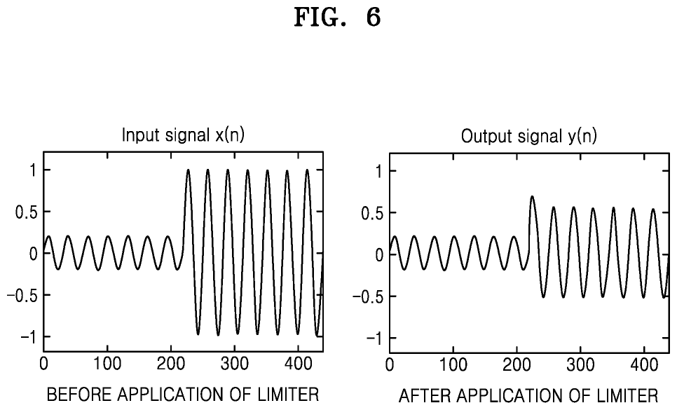

FIG. 6 illustrates a waveform before application of the limiter and a waveform after application of the limiter. When a signal with a level of 0.5 or higher is input to the limiter in the left diagram of FIG. 6, it is adjusted and output not to increase above a threshold value as in the right diagram thereof.

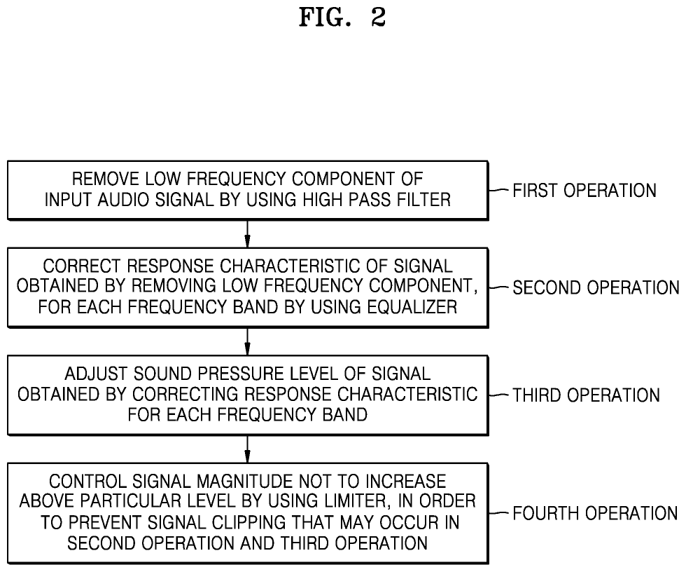

Moreover, FIG. 2 is a flowchart illustrating a sound quality improving method according to an embodiment of the disclosure. A method of improving the sound quality of a super-directional ultrasonic speaker device according to the disclosure may include: a first operation of removing a low frequency component of an input audio signal by using a high pass filter; a second operation of correcting a response characteristic of a signal obtained by removing the low frequency component, for each frequency band by using an equalizer; a third operation of adjusting a sound pressure level of a signal obtained by correcting the response characteristic for each frequency band; and a fourth operation of controlling a signal magnitude not to increase above a particular level by using a limiter, in order to prevent a signal clipping that may occur in the second operation and the third operation. The low frequency component may be about 150 Hz or less in the first operation. The third operation of adjusting the sound pressure level may remove a signal level of a first level (dB) or less not to be reproduced, compress a signal level of a second level (dB) or more, and give other signal levels a gain of 4 dB or more.

Because the sound quality improving method is different only in the category of the disclosure from the super-directional ultrasonic speaker device including the sound quality improver described above, redundant descriptions thereof will be omitted for conciseness.

However, the sound quality improving method may be implemented as a program in a digital signal processor (DSP) and may be implemented as a program such as an app in a computer device such as a PC or a mobile phone. In this case, the program may be recorded and stored in a computer-readable storage medium and may be executed in various devices such as computers and mobile phones.

The method of improving the sound quality of the super-directional ultrasonic speaker device and the super-directional ultrasonic speaker device including the same according to the embodiments of the disclosure have been described above. It should be understood that the above embodiments are illustrative and non-limitative in all respects, and the scope of the disclosure will be defined by the claims described below rather than by the detailed description described above. Also, it should be understood that the meaning and scope of the claims and all changes and modifications derived from the equivalent concept thereof are included in the scope of the disclosure.

### EXPLANATION OF REFERENCE NUMERALS DESIGNATING THE MAJOR ELEMENTS OF THE DRAWINGS

100: Ultrasonic modulator

110: Ultrasonic transducer

200: Sound quality improver

210: High pass filter

220: Equalizer

230: Sound pressure level corrector

240: Limiter

1. A method of improving sound quality of an ultrasonic speaker device, the method comprising:
a first operation of removing a low frequency component of an input audio signal by using a high pass filter;
a second operation of correcting a response characteristic of a signal obtained by removing the low frequency component, for each frequency band by using an equalizer;
a third operation of adjusting a sound pressure level of a signal obtained by correcting the response characteristic for each frequency band; and
a fourth operation of controlling a signal magnitude not to increase above a particular level by using a limiter, in order to prevent a signal clipping that may occur in the second operation and the third operation.

2. The method of claim 1, wherein the low frequency component is about 150 Hz or less in the first operation.

3. The method of claim 1, wherein the third operation of adjusting the sound pressure level removes a signal level of a first level (dB) or less not to be reproduced, compresses a signal level of a second level (dB) or more, and gives other signal levels a gain of 4 dB or more.

4. An ultrasonic speaker device comprising a sound quality improver, the sound quality improver comprising:
a high pass filter configured to remove a low frequency component of an input audio signal;
an equalizer configured to correct a response characteristic of a signal obtained by removing the low frequency component through the high pass filter, for each frequency band;
a sound pressure level corrector configured to adjust a sound pressure level of a signal obtained by correcting the response characteristic for each frequency band; and
a limiter configured to control a signal magnitude not to increase above a particular level, in order to prevent a signal clipping that may occur in the equalizer and the sound pressure level corrector.

5. The ultrasonic speaker device of claim 4, wherein the low frequency component is about 150 Hz or less

6. The ultrasonic speaker device of claim 4, wherein the sound pressure level corrector is configured to remove a signal level of a first level (dB) or less not to be reproduced, compress a signal level of a second level (dB) or more, and give other signal levels a gain of 4 dB or more.

7. (canceled)

8. A non-transitory computer-readable storage medium having recorded thereon instructions, executable by a processor, for implementing a method of improving sound quality of an ultrasonic speaker device, the computer readable recording medium comprising:
Instructions for a first operation of removing a low frequency component of an input audio signal by using a high pass filter;
Instructions for a second operation of correcting a response characteristic of a signal obtained by removing the low frequency component, for each frequency band by using an equalizer;
Instructions for a third operation of adjusting a sound pressure level of a signal obtained by correcting the response characteristic for each frequency band; and
Instructions for a fourth operation of controlling a signal magnitude not to increase above a particular level by using a limiter, in order to prevent a signal clipping that may occur in the second operation and the third operation.

9. The non-transitory computer-readable storage medium of claim 8, wherein the low frequency component is about 150 Hz or less in the first operation.

10. The non-transitory computer-readable storage medium of claim 8, wherein the third operation of adjusting the sound pressure level removes a signal level of a first level (dB) or less not to be reproduced, compresses a signal level of a second level (dB) or more, and gives other signal levels a gain of 4 dB or more.
